(19) United States
(12) Patent Application Publication
(10) Pub. No.: US 2017/0033081 A1
(43) Pub. Date: Feb. 2, 2017

(54) STACK PACKAGE AND METHOD FOR MANUFACTURING THE STACK PACKAGE

(71) Applicant: SK hynix Inc., Icheon-si Gyeonggi-do (KR)

(72) Inventors: Je Sik YOO, Seoul (KR); Jong Hyun KIM, Seoul (KR); Yo Seph JEONG, Ansan-si Gyeonggi-do (KR); Han Jun BAE, Seongnam-si Gyeonggi-do (KR)

(21) Appl. No.: 14/924,884

(22) Filed: Oct. 28, 2015

(30) Foreign Application Priority Data
Jul. 31, 2015 (KR) 10-2015-0108593

(51) Int. Cl. H01L 25/065; H01L 25/00

(52) U.S. Cl. CPC H01L 25/0657; H01L 25/50; H01L 2225/06575

(57) ABSTRACT

A stack package may include a substrate, and a first semiconductor chip mounted over the substrate. The stack package may include a support member disposed over the substrate and the first semiconductor chip, and spaced apart from the substrate and the first semiconductor chip. The stack package may include a plurality of second semiconductor chips stacked over the support member.

### CROSS-REFERENCE TO RELATED APPLICATION

The present application claims priority under 35 U.S.C. §119(a) to Korean Patent Application No. 10-2015-0108593 filed in the Korean Intellectual Property Office on Jul. 31, 2015, which is incorporated herein by reference in its entirety.

### BACKGROUND

1. Technical Field

Various embodiments generally relate to a semiconductor technology, and more particularly, to a stack package and a method for manufacturing the stack package.

2. Related Art

The trend of the electronics industry, these days, is to manufacture products at reduced costs with a high reliability while still being able to manufacture light weight, miniaturized, high speed, multi-functional and high performance products. One of the important technologies considered in designing such products relate to the package assembly technology regarding the products.

Various methods for mounting a plurality of semiconductor chips within a limited footprint have been researched as a result of electronic products being scaled down and footprints being decreased.

### SUMMARY

In an embodiment, a stack package may be provided. The stack package may include a substrate, and a first semiconductor chip mounted over the substrate. The stack package may include a support member disposed over the substrate and the first semiconductor chip, and spaced apart from the substrate and the first semiconductor chip. The stack package may include a plurality of second semiconductor chips stacked over the support member.

The support member may be formed to extend across the substrate in one direction.

The support member may be formed in a line type which covers a first portion of a top surface of the substrate and exposes a second portion of the top surface of the substrate outside the first portion.

The substrate may comprise bond fingers which are electrically connected with the second semiconductor chips, over the second portion.

The stack package may further comprise conductive connection members electrically connecting the second semiconductor chips and the bond fingers. The conductive connection members may comprise conductive wires.

The support member may comprise a core substrate or a metal alloy plate. The core substrate may comprise a glass fiber substrate which is impregnated with resin. The metal alloy plate may comprise an alloy plate which contains at least one of FeC and MnCr.

The stack package may further comprise a molding part filling a space between the substrate and the first semiconductor chip and the support member, and enclosing the first semiconductor chip, the support member and the second semiconductor chips.

The second semiconductor chip may have an area larger than the first semiconductor chip.

The support member may have an area larger than the first semiconductor chip and an area equal to or greater than the second semiconductor chip.

The first semiconductor chip may comprise a logic chip, and the second semiconductor chips may comprise memory chips.

The support member may be configured to prevent increasing a thickness of the stack package caused by attaching the support member to a lowermost second semiconductor chip.

The support member may be attached to the lowermost second semiconductor chip through an adhesive member, and the support member includes an opening.

The support member may be configured to minimize increasing a thickness of the stack package caused by attaching the support member to a lowermost second semiconductor chip.

The support member may be attached to the lowermost second semiconductor chip through an adhesive member, and the support member includes an opening.

The stack package may further comprise an adhesive member attaching the support member and a lowermost second semiconductor chip.

The support member may include one or more openings configured to accommodate an adhesive member.

The adhesive member may be interposed between a bottom surface of the lowermost second semiconductor chip and a top surface of the support member.

The support member may have a mesh shape having a plurality of openings in which the adhesive member is accommodated. Each of the openings may have a sectional shape of a circle, an oval or a polygon when viewed on the top.

The support member may have a thickness greater than the adhesive member. The support member may have a thickness of 100 to 120 μm, and the adhesive member may have a thickness of 20 to 40 μm.

The adhesive member may comprise first portions interposed between the bottom surface of the lowermost second semiconductor chip and the top surface of the support member, and second portions accommodated in the openings.

The adhesive member may be formed to be entirely accommodated in the openings.

The openings may be configured to allow the adhesive member to attach with the support member and a lowermost second semiconductor chip without increasing the thickness of the stack package.

A top surface of the adhesive member may be substantially flush with the top surface of the support member, and the top surface of the support member and the bottom surface of the lowermost second semiconductor chip directly contact each other.

The support member may have a thickness less than the adhesive member.

The adhesive member may comprise first portions interposed between the top surface of the support member and the bottom surface of the lowermost second semiconductor chip, second portions accommodated in the openings, and third portions disposed under a bottom surface of the support member.

The second semiconductor chips may have the same thickness.

The stack package may further comprise an adhesive member contacting with both the support member and a second semiconductor chip, wherein the support member may include an opening configured to accommodate the adhesive member.

In an embodiment, a method for manufacturing a stack package may be provided. The method for manufacturing the stack package may include mounting first semiconductor chips over a plurality of unit substrates, respectively, which are formed over a strip substrate. The method for manufacturing the stack package may include disposing dams over the strip substrate. The method for manufacturing the stack package may include disposing support members over the dams such that the support members are separated from the strip substrate and the first semiconductor chips and extend across the unit substrates. The method for manufacturing the stack package may include stacking a plurality of second semiconductor chips over the support members over the unit substrates.

The dams may be disposed over both ends of the strip substrate facing away from each other in the one direction.

The dams may be disposed over both ends of the strip substrate which face away from each other in the one direction and at one or more positions between both the ends of the strip substrate.

Each of the dams may be formed in a line type extending in a direction substantially perpendicular to a lengthwise direction of the support members.

Each of the dams may be formed by a plurality of structures arranged in the direction substantially perpendicular to the lengthwise direction of the support members.

The dams may be formed by a solder resist film or dummy chips.

The support members may be formed by a core substrate or a metal alloy plate. The core substrate may comprise a glass fiber substrate which is impregnated with resin. The metal alloy plate may comprise an alloy plate containing at least one of FeC and MnCr.

Lowermost second semiconductor chips among the second semiconductor chips may be stacked in such a manner that the lowermost second semiconductor chips are attached with the support members with adhesive members without increasing a thickness of the stack package due to the adhesive members.

The support members may include an opening.

The method may further comprise forming adhesive members under bottom surfaces of the second semiconductor chips, before the stacking of the second semiconductor chips, wherein the stacking of the second semiconductor chips may be performed in such a manner that lowermost second semiconductor chips and the support members are attached and the second semiconductor chips are attached, by the medium of the adhesive members.

The support members may include one or more openings configured to accommodate the adhesive members.

The support members may have a mesh shape including a plurality of openings, and the attaching of the lowermost second semiconductor chips may be performed in such a manner that portions of the adhesive members formed under bottom surfaces of the lowermost second semiconductor chips are accommodated in the openings.

The support members may have a mesh shape which includes a plurality of openings, and the attaching of the lowermost second semiconductor chips may be performed in such a manner that the adhesive members formed under bottom surfaces of the lowermost second semiconductor chips are entirely accommodated in the openings.

The method may further comprise forming a molding part which fills spaces between the strip substrate and the first semiconductor chips and the support members, and encloses the first semiconductor chips, the support members and the second semiconductor chips, after the stacking of the second semiconductor chips.

The method may further comprise forming conductive connection members which electrically connect bonding pads of the second semiconductor chips and the unit substrates, after the stacking of the second semiconductor chips and before the forming of the molding part.

The conductive connection members may comprise conductive wires.

The method may further comprise individualizing the stack package by cutting the molding part, the support members and the strip substrate such that the stack package is separated by the unit of each unit substrate, after the forming of the molding part.

### BRIEF DESCRIPTION OF THE DRAWINGS

FIG. 1 is a top view illustrating a representation of an example of a stack package in accordance with an embodiment.

FIG. 2 is a cross-sectional view taken along the line A-A′ of FIG. 1.

FIG. 3 is a cross-sectional view taken along the line B-B′ of FIG. 1.

FIG. 4 is a top view illustrating a representation of an example of the top surface of the substrate illustrated in FIG. 1.

FIG. 5 is a cross-sectional view illustrating a representation of an example of a stack package in accordance with an embodiment.

FIG. 6 is a cross-sectional view illustrating a representation of an example of a stack package in accordance with an embodiment.

FIG. 7 is a cross-sectional view illustrating a representation of an example of a stack package in accordance with an embodiment.

FIGS. 8 to 17 are views to assist in the explanation of a method for manufacturing a stack package in accordance with an embodiment.

FIG. 18 is a block diagram illustrating a representation of an example of an electronic system including the stack package in accordance with the embodiments.

FIG. 19 is a block diagram illustrating a representation of an example of a memory card including the stack package in accordance with the embodiments.

### DETAILED DESCRIPTION

Hereinafter, a stack package and a method for manufacturing the stack package will be described below with reference to the accompanying drawings through various examples of embodiments.

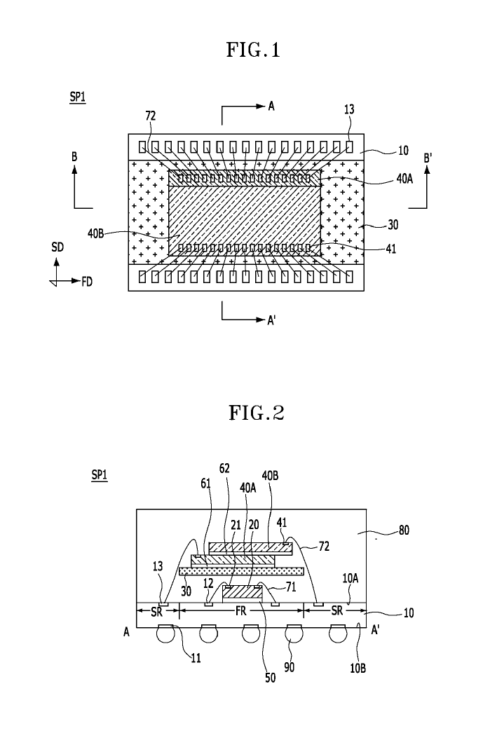

Referring to FIGS. 1 to 3, a stack package SP1 in accordance with an embodiment may include a substrate 10, a first semiconductor chip 20, a support member 30, and a plurality of second semiconductor chips 40A and 40B. In an embodiment, aside from the stack package SP1, there may be provided a first adhesive member 50, second adhesive members 61 and 62, first and second conductive connection members 71 and 72, a molding part 80, and external connection terminals 90. In order to facilitate understanding, the illustration of the molding part 80 is omitted in FIG. 1.

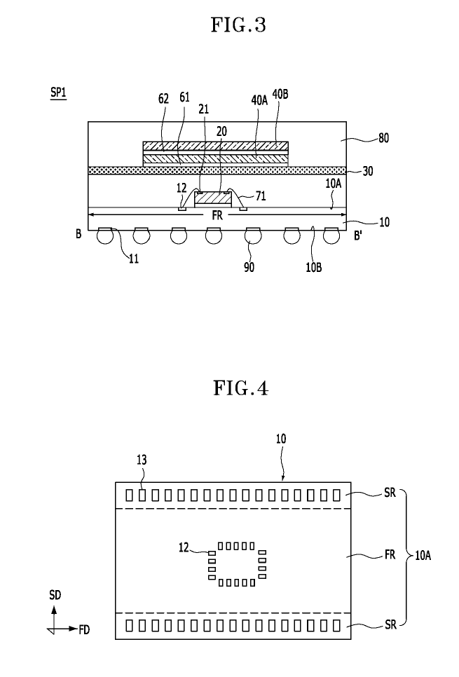

The substrate 10 may be a printed circuit board. The substrate 10 may have a top surface 10A and a bottom surface 10B, and may include external electrodes 11 on the bottom surface 10B. The external connection terminals 90 such as solder balls, conductive bumps and conductive posts may be attached to the external electrodes 11, respectively. In the embodiments illustrated in FIGS. 2 and 3 the solder balls are used, for example, as the external connection terminals 90. The stack package SP1 may be mounted to an external device (not illustrated), for example, a main board, by the medium of the external connection terminals 90.

Referring to FIGS. 2 to 4, the top surface 10A of the substrate 10 may be divided into a first region FR and a second region SR which is positioned outside the first region FR. The first region FR may extend across the top surface 10A of the substrate 10 in a first direction FD defined in FIG. 4, and the second region SR may be arranged side by side to the first region FR on one side or both sides of the first region FR when viewed in the second direction SD.

The substrate 10 may have first bond fingers 12 on the first region FR, and may have second bond fingers 13 on the second region SR. The first bond fingers 12 may be electrically connected with the first semiconductor chip 20, and the second bond fingers 13 may be electrically connected with the second semiconductor chips 40A and 40B. This construction will be described later.

While not illustrated, the substrate 10 may include circuit lines which are formed in different layers and conductive vias which electrically connect the circuit lines formed in the different layers. The first and second bond fingers 12 and 13 formed on the top surface 10A of the substrate 10 may be electrically connected with the external electrodes 11 which are formed on the bottom surface 10B of the substrate 10, through the circuit lines and the conductive vias.

While an embodiment illustrates an example in which the substrate 10 is constructed by a printed circuit board, it is to be noted that the technical concept of the disclosure is not limited to such an example. For example, the substrate 10 may be any one of, for example but not limited to, a lead frame, a flexible substrate, and an interposer.

Referring again to FIGS. 2 and 3, the first semiconductor chip 20 may have first bonding pads 21 on the active surface thereof. A circuit unit (not illustrated) configured by an integrated circuit, in which individual elements such as transistors, resistors, capacitors, fuses and the likes necessary for a chip operation are electrically interconnected, may be formed in the first semiconductor chip 20. The first bonding pads 21 are external contacts of the circuit unit for electrical connection with an exterior and may be electrically connected with the circuit unit.

The first semiconductor chip 20 may be mounted to the first region FR of the top surface 10A of the substrate 10. For example, the first adhesive member 50 constructed by a tape or a resin type adhesive may be formed on the inactive surface of the first semiconductor chip 20 facing away from the active surface. The first semiconductor chip 20 may be attached to the first region FR of the top surface 10A of the substrate 10 by the medium of the first adhesive member 50. The first bonding pads 21 of the first semiconductor chip 20 may be electrically connected with the first bond fingers 12 of the substrate 10 by the medium of the first conductive connection members 71. The first conductive connection members 71 may include conductive wires.

Although not illustrated, the first semiconductor chip 20 may have a plurality of bumps which are electrically connected with the first bonding pads 21 on the active surface on which the first bonding pads 21 are formed, and may be flip-chip bonded to the first bond fingers 12 of the substrate 10 by the medium of the bumps.

The support member 30 is disposed over the substrate 10 and the first semiconductor chip 20 to be separated from the substrate 10 and the first semiconductor chip 20.

Referring again to FIGS. 1 to 3, the support member 30 may extend across the substrate 10 in the first direction FD over the substrate 10 and the first semiconductor chip 20. The support member 30 may cover the first region FR of the top surface 10A of the substrate 10 and the first semiconductor chip 20 mounted to the first region FR, and may expose the second region SR of the substrate 10.

The support member 30 may have an area corresponding to the first region FR of the substrate 10, and may have an area larger than the first semiconductor chip 20 mounted to the first region FR of the substrate 10.

The thickness of the support member 30 may have the range of 100 to 120 μm, and a core substrate or a metal alloy plate may be used as the support member 30. The core substrate may include a glass fiber substrate impregnated with resin, and the metal alloy plate may include an alloy plate which contains at least one of FeC and MnCr.

Each of the second semiconductor chips 40A and 40B may have second bonding pads 41 on the active surface thereof. A circuit unit (not illustrated) configured by an integrated circuit, in which individual elements such as transistors, resistors, capacitors, fuses and the likes necessary for a chip operation are electrically interconnected, may be formed in each of the second semiconductor chips 40A and 40B. The second bonding pads 41 is external contacts of the circuit unit for electrical connection with an exterior and may be electrically connected with the circuit unit. The second bonding pads 41 may be arranged in a line or in a plurality of lines including at least 2 lines along respective one side portions of the active surfaces of the second semiconductor chips 40A and 40B.

The second semiconductor chips 40A and 40B may be ones which are manufactured on the same wafer and are then individualized or may be ones which are obtained from different wafers manufactured through the same manufacturing process in the same manufacturing line, and may have the same thickness.

Each of the second semiconductor chips 40A and 40B may have an area larger than the first semiconductor chip 20, and may have an area equal to or smaller than the support member 30.

The second semiconductor chips 40A and 40B may be a different kind of chips from the first semiconductor chip 20. For example, the second semiconductor chips 40A and 40B may be volatile memory chips such as DRAMs or nonvolatile memory chips such as flash memories, and the first semiconductor chip 20 may be a logic chip which controls the second semiconductor chips 40A and 40B. The second semiconductor chips 40A and 40B may be the same kind of chips as the first semiconductor chip 20. For example, the first semiconductor chip 20 and the second semiconductor chips 40A and 40B may be volatile memory chips such as DRAMs or nonvolatile memory chips such as flash memories.

The second adhesive members 61 and 62 may be formed on the inactive surfaces, respectively, of the second semiconductor chips 40A and 40B. The second adhesive members 61 and 62 may be adhesive tapes or resin type adhesives, and may have the thickness of 20 to 40 μm.

The second semiconductor chips 40A and 40B may be stacked on the support member 30 by the medium of the second adhesive members 61 and 62. The second adhesive member 61 which attaches the support member 30 and the lowermost second semiconductor chip 40A may be interposed between the top surface of the support member 30 and the bottom surface of the lowermost second semiconductor chip 40A, and the second adhesive member 62 attaching the second semiconductor chips 40A and 40B may be interposed between the top surface of the lower second semiconductor chip 40A and the bottom surface of the upper second semiconductor chip 40B.

In an embodiment, the second semiconductor chips 40A and 40B are stacked in a zigzag pattern such that the second bonding pads 41 of the second semiconductor chips 40A and 40B are exposed on left and right side portions when viewed in the second direction SD. While it was illustrated and described in an embodiment that the second semiconductor chips 40A and 40B are stacked in a zigzag pattern, it is to be noted that the second semiconductor chips 40A and 40B may be stacked vertically or the second semiconductor chips 40A and 40B may be stacked in a step-like shape such that the second bonding pads 41 are exposed on step portions.

The second connection members 72 may electrically connect the second bonding pads 41 of the second semiconductor chips 40A and 40B and the second bond fingers 13 of the substrate 10. The second connection members 72 may include conductive wires.

The molding part 80 may be to protect the elements mounted to the substrate 10 from an external device and external circumstances. The molding part 80 may be formed on the top surface 10A of the substrate 10 in such a way as to fill the space between the substrate 10 and the first semiconductor chip 20 and the support member 30, and may enclose the first semiconductor chip 20, the support member 30, the second semiconductor chips 40A and 40B and the first and second conductive connection members 71 and 72. Both ends of the support member 30 facing away from each other when viewed in the first direction FD defined in FIG. 1 may be exposed to an exterior, and may be substantially flush with the side surfaces of the molding part 80.

The molding part 80 may be constructed by one or at least two of an epoxy resin having a filler, an epoxy acrylate having a filler, and a polymer composite material such as a polymer having a filler.

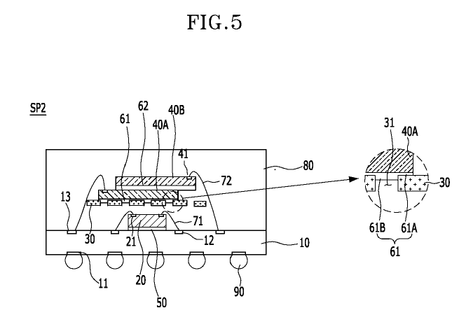

While it was illustrated and described in an embodiment that the second adhesive member 61 attaching the support member 30 and the lowermost second semiconductor chip 40A is interposed between the top surface of the support member 30 and the bottom surface of the lowermost second semiconductor chip 40A, it is to be noted that the technical concept of the disclosure is not limited to such an example and modification may be made into a variety of types which will be described below with reference to FIGS. 5 to 7.

FIGS. 5 to 7 are cross-sectional views respectively illustrating stack packages SP2, SP3 and SP4 in accordance with various embodiments. In the embodiments to be described below with reference to FIGS. 5 to 7, the same technical terms and the same reference numerals will be used to refer to substantially the same components as the components of the embodiment described above with reference to FIGS. 1 to 4, and repeated descriptions will be omitted herein.

Referring to FIG. 5, a support member 30 may have a mesh shape having a plurality of openings 31 in which a second adhesive member 61 for attaching the support member 30 and a lowermost second semiconductor chip 40A is accommodated, and the second adhesive member 61 may be partially accommodated in the openings 31 of the support member 30.

In an embodiment, the second adhesive member 61 may include first portions 61A which are interposed between the top surface of the support member 30 and the bottom surface of the lowermost second semiconductor chip 40A and second portions 61B which are accommodated in the openings 31.

The support member 30 may have the thickness of 100 to 120 μm, and the second adhesive member 61 may have a thickness thinner than the support member 30, for example, the thickness of 20 to 40 μm. While not illustrated, the openings 31 may have the sectional shape of, for example but not limited to, a circle, an oval or a polygon when viewed on the top.

According to an embodiment illustrated in FIG. 5, since the support member 30 has the plurality of openings 31, the second portions 61B of the second adhesive member 61 are accommodated in the openings 31. Accordingly, as the contact area between the second adhesive member 61 and the support member 30 is increased, an adhesive force may be increased. Since the second portions 61B of the second adhesive member 61 are accommodated in the openings 31, advantages may be provided in that the volume and the thickness of the second adhesive member 61 disposed on the top surface of the support member 30 are decreased and thus the overall thickness of the stack package SP2 is decreased.

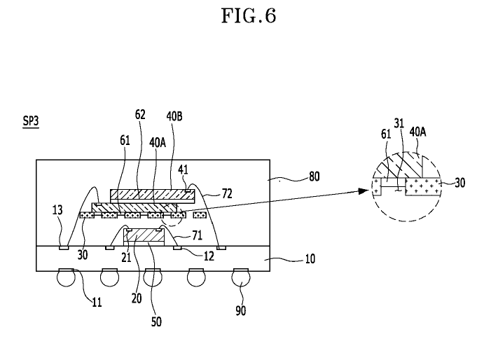

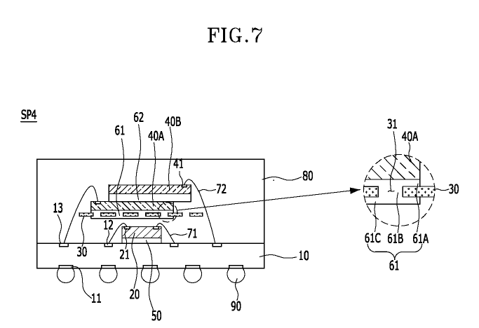

Referring to FIG. 6, a support member 30 may have a mesh shape which has a plurality of openings 31 in which a second adhesive member 61 for attaching the support member 30 and a lowermost second semiconductor chip 40A is accommodated, and the second adhesive member 61 may be entirely accommodated in the openings 31 of the support member 30.

The top surface of the second adhesive member 61 may be substantially flush with the top surface of the support member 30, and the bottom surface of the lowermost second semiconductor chip 40A and the top surface of the support member 30 may directly contact each other.

The support member 30 may have the thickness of 100 to 120 μm, and the second adhesive member 61 may have a thickness thinner than the support member 30, for example, the thickness of 20 to 40 μm. Because the top surface of the second adhesive member 61 is substantially flush with the top surface of the support member 30 and the second adhesive member 61 has the thickness thinner than the support member 30, the bottom surface of the second adhesive member 61 is positioned in the openings 31.

According to an embodiment illustrated in FIG. 6, since the second adhesive member 61 is entirely accommodated in the openings 31 of the support member 30, an additional space for disposing the second adhesive member 61 is not needed, and thus, the thickness of the stack package SP3 may be decreased.

Referring to FIG. 7, a support member 30 may have a mesh shape which has a plurality of openings 31 in which a second adhesive member 61 for attaching the support member 30 and a lowermost second semiconductor chip 40A is accommodated, and the support member 30 may have a thickness thinner than or less than the second adhesive member 61.

The second adhesive member 61 may include first portions 61A which are interposed between the top surface of the support member 30 and the bottom surface of the lowermost second semiconductor chip 40A, second portions 61B which are accommodated in the openings 31, and third portions 61C which are disposed under the bottom surface of the support member 30.

Hereafter, examples of methods for manufacturing a stack package in accordance with various embodiments will be described.

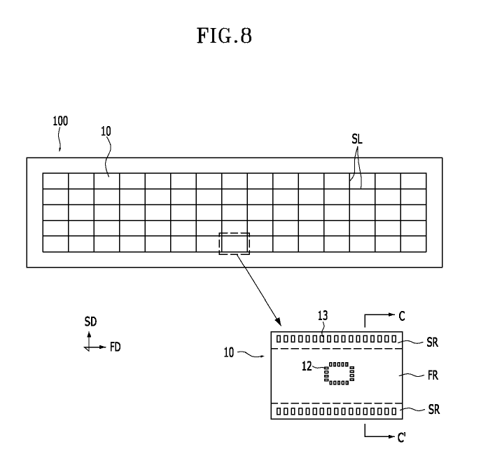

Referring to FIG. 8, a strip substrate 100 which is formed with a plurality of unit substrates 10 is prepared.

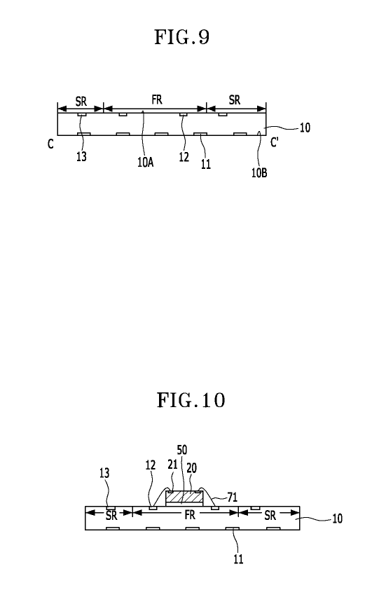

The unit substrates 10 may be formed on the strip substrate 100 to be separated from one another by saw lines SL. The saw lines SL represent spaces between adjacent unit substrates 10. For example, the unit substrates 10 may be arranged in the type of a matrix by forming rows and columns with the saw lines SL interposed between the rows and between the columns. It is illustrated as an example in an embodiment that 75 unit substrates 10 are arranged in the type of a 15 (in a first direction FD)×5 (in a second direction SD) matrix. However, it is to be noted that the technical concept of the disclosure is not limited to such an example, and the number of the unit substrates 10 formed on the strip substrate 100 and the arrangement type of the unit substrates 10 may be changed in a variety of ways. FIG. 9 is a cross-sectional view taken along the line C-C′ of FIG. 8, illustrating a unit substrate 10.

Referring to FIGS. 8 to 9, each unit substrate 10 may have a top surface 10A and a bottom surface 10B. The top surface 10A of each unit substrate 10 may be divided into a first region FR and a second region SR which is positioned outside the first region FR. The first region FR may extend across the top surface 10A of the unit substrate 10 in the first direction FD defined in FIG. 8, and the second region SR may be arranged side by side to the first region FR on one side or both sides of the first region FR when viewed in the second direction SD.

Each unit substrate 10 may have first bond fingers 12 on the first region FR of the top surface 10A, and may have second bond fingers 13 on the second region SR of the top surface 10A. Each unit substrate 10 may have external electrodes 11 on the bottom surface 10B.

While not illustrated, each unit substrate 10 may include circuit lines which are formed in different layers and conductive vias which electrically connect the circuit lines formed in the different layers. The first and second bond fingers 12 and 13 formed on the top surface 10A of the unit substrate 10 may be electrically connected with the external electrodes 11 which are formed on the bottom surface 10B of the unit substrate 10, through the circuit lines and the conductive vias.

Referring to FIG. 10, the inactive surface of a first semiconductor chip 20 is attached to the first region FR of the top surface 10A of the unit substrate 10 by the medium of a first adhesive member 50. As the first adhesive member 50, a tape or a resin type adhesive may be used.

First conductive connection members 71 are formed to electrically connect the first bonding pads 21 of the first semiconductor chip 20 and the first bond fingers 12 of the unit substrate 10. As the first conductive connection members 71, conductive wires may be used.

Although not illustrated, a plurality of bumps may be formed on the active surface of the first semiconductor chip 20 having the first bonding pads 21, to be electrically connected with the first bonding pads 21, and the first semiconductor chip 20 may be flip-chip bonded to the first bond fingers 12 of the unit substrate 10 by the medium of the bumps.

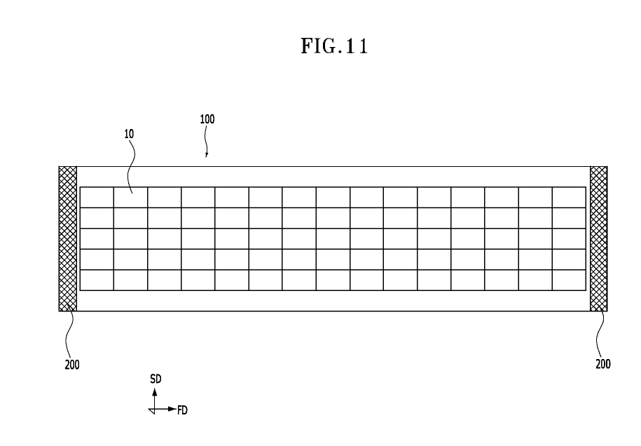

Referring to FIG. 11, dams 200 are disposed on the strip substrate 100.

The dams 200 play the role of supporting support members which are to be subsequently disposed, and may be arranged on both ends of the strip substrate 100 which face away from each other in the first direction FD. As the dams 200, line type structures extending in the second direction SD perpendicular to the first direction FD may be used, or a plurality of structures which are arranged in the second direction SD may be used. For example, as the dams 200, a solder resist film or a plurality of dummy chips may be used.

In the example where dummy chips are used as the dams 200, the dams 200 may be attached to the strip substrate 100 by the medium of an adhesive member such as a double-sided tape or a resin type adhesive. In the example where a solder resist film is used as the dams 200, the dams 200 may be directly attached to the strip substrate 100 without using a separate adhesive member.

The dams 200 may have a predetermined height such that the support members to be disposed on the dams 200 in a subsequent process may be separated from the strip substrate 100, first semiconductor chips 20 and first conductive connection members 71 by at least a predetermined distance. For example, the dams 200 may have the height of 90 to 120 μm.

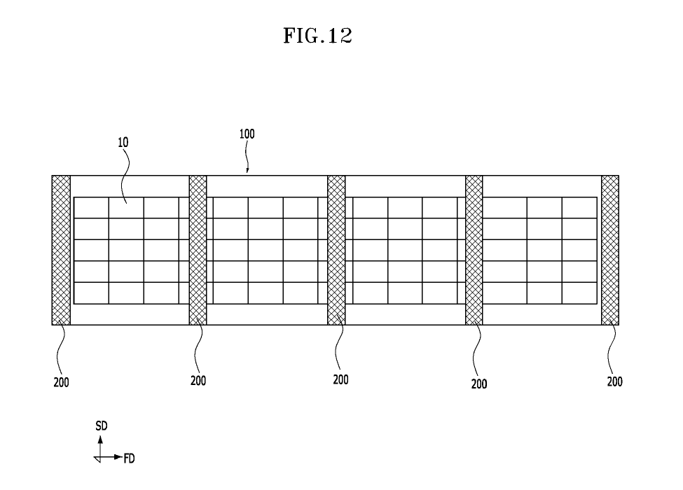

Referring to FIG. 12, dams 200 may be arranged at one or more positions between both the ends of the strip substrate 100, such that the support members may also be supported over inner parts of the strip substrate 100. For reference, in FIGS. 11 and 12, for the sake of simplification in drawings, the illustration of the first and second bond fingers 12 and 13, the first semiconductor chip 20 and the first conductive connection members 71 is omitted.

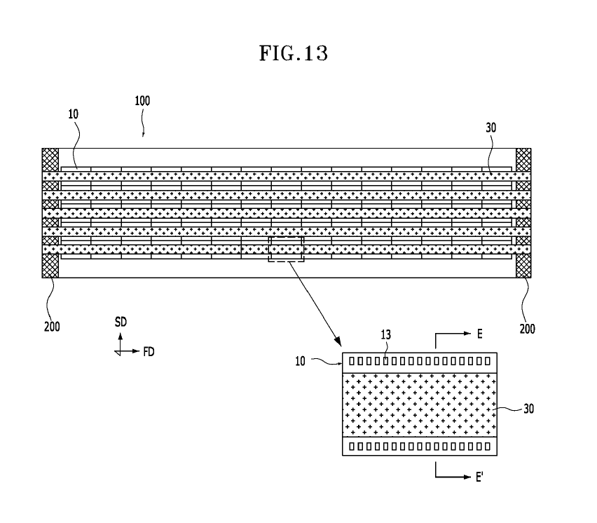

Referring to FIG. 13, support members 30 are disposed on the dams 200 in such a way as to extend across the strip substrate 100 in the first direction FD.

In the example where the dams 200 are formed using dummy chips, the support members 30 may be attached to the dams 200 by the medium of an adhesive member such as a double-sided tape or a resin type adhesive. In the example where the dams 200 are formed using a solder resist film, the support members 30 may be directly attached to the dams 200 without using a separate adhesive member.

The thickness of the support members 30 may have the range of 100 to 120 μm, and a core substrate or a metal alloy plate may be used as the support members 30. The core substrate may include a glass fiber substrate impregnated with resin, and the metal alloy plate may include an alloy plate which contains at least one of FeC and MnCr. While not illustrated, each of the support members 30 may have a mesh shape which has a plurality of openings.

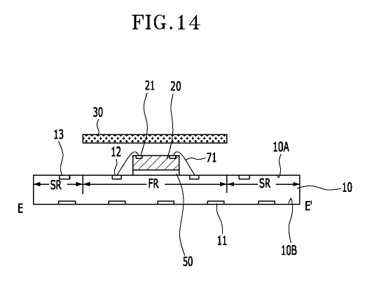

The support members 30 are supported by the dams 200 and are separated from the unit substrates 10 and first semiconductor chips 20 mounted to the unit substrates 10, by at least the predetermined distance, and this construction is illustrated in FIG. 14 which is a cross-sectional view taken along the line E-E′ of FIG. 13.

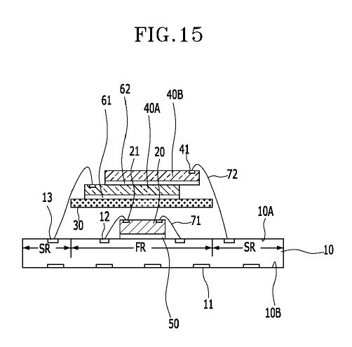

Referring to FIG. 15, a plurality of second semiconductor chips 40A and 40B on the active surfaces of which pluralities of second bonding pads 41 are formed are prepared.

The second semiconductor chips 40A and 40B may be ones which are manufactured on the same wafer and are then individualized or may be ones which are obtained from different wafers manufactured through the same manufacturing process in the same line, and may have the same thickness.

The respective second semiconductor chips 40A and 40B may have an area larger than the first semiconductor chip 20, and may have an area smaller than the support member 30.

The second semiconductor chips 40A and 40B may be a different kind of chips from the first semiconductor chip 20. For example, the second semiconductor chips 40A and 40B may be volatile memory chips such as DRAMs or nonvolatile memory chips such as flash memories, and the first semiconductor chip 20 may be a logic chip which controls the second semiconductor chips 40A and 40B. The second semiconductor chips 40A and 40B may be the same kind of chips as the first semiconductor chip 20. For example, the first semiconductor chip 20 and the second semiconductor chips 40A and 40B may be volatile memory chips such as DRAMs or nonvolatile memory chips such as flash memories.

Second adhesive members 61 and 62 may be formed on the inactive surfaces of the second semiconductor chips 40A and 40B. The second adhesive members 61 and 62 may include tapes or resin type adhesives, and may have the thickness of 20 to 40 μm.

The second semiconductor chips 40A and 40B are stacked on the support member 30 which is disposed over the unit substrate 10, by the medium of the second adhesive members 61 and 62. In an embodiment illustrated in FIG. 15, the second semiconductor chips 40A and 40B are stacked in a zigzag pattern such that the second bonding pads 41 are exposed on left and right side portions when viewed in the second direction SD.

In other embodiments, the second semiconductor chips 40A and 40B may be vertically stacked, and the second semiconductor chips 40A and 40B may be stacked in a step-like shape such that the second bonding pads 41 are exposed on step portions. In an embodiment, the lowermost second semiconductor chips 40A may be attached over the support member 30 in such a manner that a lower surface of the adhesive members 61 formed bottom surface of the lowermost second semiconductor chips 40A are contacted with a upper surface of the support member 30. While not illustrated, the support members 30 may have a mesh shape including a plurality of openings, and the lowermost second semiconductor chips 40A may be attached over the support member 30 in such a manner that portions of the adhesive members 61 formed under bottom surfaces of the lowermost second semiconductor chips are accommodated in the openings, or the lowermost second semiconductor chips 40A may be attached over the support member 30 in such a manner that the adhesive members 61 formed under bottom surfaces of the lowermost second semiconductor chips 40A are entirely accommodated in the openings.

Second conductive connection members 72 are formed to electrically connect the second bonding pads 41 of the second semiconductor chips 40A and 40B and the second bond fingers 13 of the unit substrate 10. As the second conductive connection members 72, conductive wires may be used.

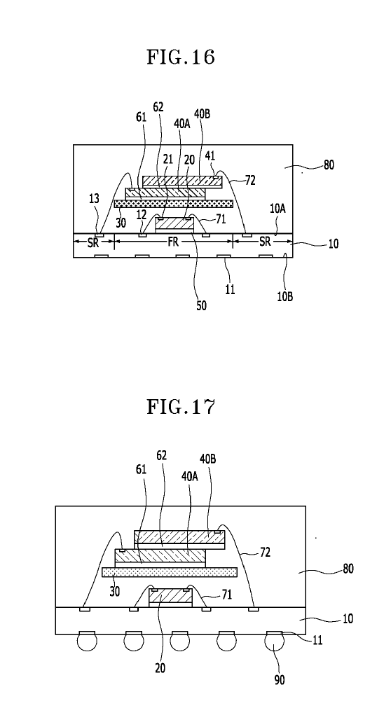

Referring to FIG. 16, through a molding process, a molding part 80 is formed on the top surface 10A of the unit substrate 10 such that the molding part 80 fills the space between the support member 30 and the unit substrate 10 and the space between the support member 30 and the first semiconductor chip 20 and encloses the first semiconductor chip 20, the support member 30, the second semiconductor chips 40A and 40B and the first and second conductive connection members 71 and 72. As the material of the molding part 80, one or at least two of an epoxy resin having a filler, an epoxy acrylate having a filler, and a polymer composite material such as a polymer having a filler may be used.

Referring to FIG. 17, external connection terminals 90 are formed on the external electrodes 11 which are formed on the bottom surface 10B of the unit substrate 10. As the external connection terminals 90, solder balls, conductive bumps or conductive posts may be used. The embodiment illustrated in FIG. 17 illustrates the example where solder balls are used as the external connection terminals 90.

Thereafter, while not illustrated, by cutting the strip substrate 100, the support members 30 and the molding part 80 such that the unit substrates 10 are individually separated from one another, the stack package SP1 illustrated in FIG. 2 may be formed.

Examples of effects achieved by the above-described embodiments may be as follows.

As a way of stacking a large-sized semiconductor chip over a small-sized semiconductor chip, an overhang wire bonding structure is used, in which an end portion of an upper semiconductor chip overhangs a lower semiconductor chip to provide an overhang portion and bonding wires are connected to the overhang portion. Since the overhang portion is held substantially freely in the air, in the course of connecting the bonding wires to the overhang portion by using a wire capillary in the wire bonding process, a phenomenon may occur in which the overhang portion bounces up and down by the pressure applied by the wire capillary to the overhang portion. Such a bouncing phenomenon may cause an imprecise connection of a bonding wire, and may lead to a defect such as a crack in the overhang portion. In the above-described embodiments, since a support member which firmly supports an upper semiconductor chip is introduced to prevent the upper semiconductor chip from overhanging, it is possible to effectively suppress occurrence of the phenomenon in which the upper semiconductor chip bounces, and accordingly, it is possible to prevent occurrence of a bonding wire connection fail, a defect such as a crack in an overhang portion, or the like.

As another way of stacking a large-sized semiconductor chip over a small-sized semiconductor chip, a method is used, in which a dielectric layer burying the small-sized semiconductor chip is formed and the large-sized semiconductor chip is stacked on the dielectric layer. In order to bury a lower semiconductor chip, the dielectric layer should have flowability. In this regard, if the flowability of the dielectric layer is small, a defect may occur in that the lower semiconductor chip may not be properly buried. Also, if the flowability of the dielectric layer is small, since a step coverage characteristic is poor, the top surface of the dielectric layer may convexly protrude upward along the profile of the lower semiconductor chip buried in the dielectric layer. That is to say, a bowing may be formed in the dielectric layer. If an upper semiconductor chip is attached to such a dielectric layer, a phenomenon may occur, in which the upper semiconductor chip warps along the profile of the dielectric layer having the bowing formed therein or the upper semiconductor chip is not properly attached to but lifts from the dielectric layer. Such a warpage or lifting phenomenon may become serious as the number of upper semiconductor chips to be stacked increases. Accordingly, since the number of upper semiconductor chips to be stacked is limited, it may be difficult to manufacture a package of a high capacity. Moreover, in the case of subsequently performing a wire bonding process, since the upper semiconductor chip has warped, a shade is likely to be formed on a bonding pad and thus it is difficult to figure out the position of the bonding pad, whereby it may be impossible to perform the wire bonding process. Moreover, as the upper semiconductor chip has warped, the position of a bonding pad may vary, and due to this fact, in the case of subsequently performing the wire bonding process, a wire capillary and the bonding pad may be misaligned with each other, whereby a wire bonding fail may occur. A hardening process for hardening the dielectric layer is performed after stacking the upper semiconductor chip on the dielectric layer, in the case where the flowability of the dielectric layer is large, a phenomenon may occur, in which the upper semiconductor chip shifts according to the flow of the dielectric layer flowing in the hardening process. If the upper semiconductor chip has shifted, the position of a bonding pad may vary, and, in the case of subsequently performing the wire bonding process, a wire capillary and the bonding pad may be misaligned with each other, whereby a wire bonding fail may occur. In the embodiments described above, since the support member which supports the upper semiconductor chip over the lower semiconductor chip is introduced, it is not necessary to form a dielectric layer which buries the lower semiconductor chip. As a consequence, the phenomenon caused due to the use of the dielectric layer having flowability to bury the lower semiconductor chip, that is, the phenomenon in which the upper semiconductor chip warps or lifts or the phenomenon in which the upper semiconductor chip shifts may be prevented originally. Accordingly, the bonding wire connection fail may be prevented, and the number of upper semiconductor chips to be stacked may be increased to contribute to the manufacture of a package of a high capacity.

The above-described stack packages may be applied to various semiconductor devices and package modules.

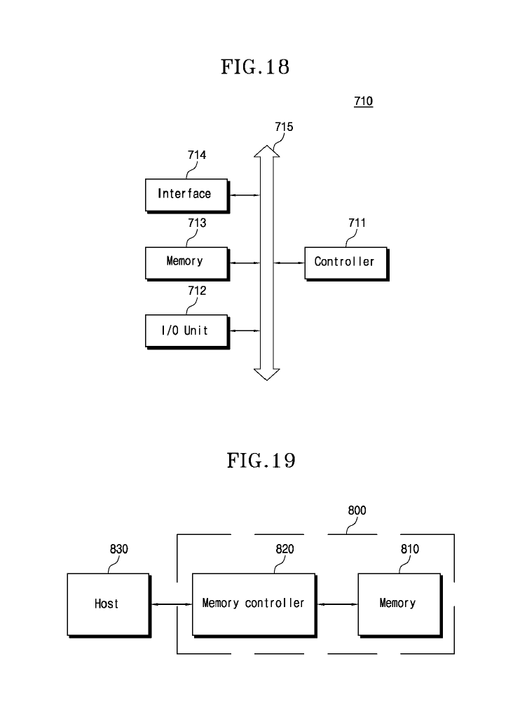

Referring to FIG. 18, the stack packages in accordance with the various embodiments may be applied to an electronic system 710. The electronic system 710 may include a controller 711, an input/output unit 712 (i.e., I/O unit), and a memory 713. The controller 711, the input/output unit 712 and the memory 713 may be electrically connected with one another through a bus 715 which provides a data movement path.

For example, the controller 711 may include at least one microprocessor, at least one digital signal processor, at least one microcontroller, and at least one of logic circuits capable of performing the same functions as these components. The memory 713 may include at least one among the stack packages in accordance with the embodiments. The input/output unit 712 may include at least one selected among a keypad, a keyboard, a display device, a touch screen, and so forth. The memory 713 as a device for storing data may store data or/and commands to be executed by the controller 711 or the like.

The memory 713 may include a volatile memory device such as a DRAM or/and a nonvolatile memory device such as a flash memory. For example, a flash memory may be mounted to an information processing system such as a mobile terminal or a desk top computer. The flash memory may be configured as a solid state drive (SSD). In this case, the electronic system 710 may stably store a large amount of data in a flash memory system.

The electronic system 710 may further include an interface 714 which is set to be able to transmit and receive data to and from a communication network. The interface 714 may be a wired or wireless type. For example, the interface 714 may include an antenna, a wired transceiver or a wireless transceiver.

The electronic system 710 may be understood as a mobile system, a personal computer, a computer for an industrial use or a logic system which performs various functions. For example, the mobile system may be any one among a personal digital assistant (PDA), a portable computer, a tablet computer, a mobile phone, a smart phone, a wireless phone, a laptop computer, a memory card, a digital music system and an information transmission/reception system.

In the case where the electronic system 710 is a device capable of performing wireless communication, the electronic system 710 may be used in a communication system such as CDMA (code division multiple access), GSM (global system for mobile communications), NADC (north American digital cellular), E-TDMA (enhanced-time division multiple access), WCDMA (wideband code division multiple access), CDMA2000, LTE (long term evolution) and Wibro (wireless broadband Internet).

Referring to FIG. 19, the stack packages in accordance with the embodiments may be provided in the form of a memory card 800. For example, the memory card 800 may include a memory 810 such a nonvolatile memory device and a memory controller 820. The memory 810 and the memory controller 820 may store data or read stored data.

The memory 810 may include at least any one among nonvolatile memory devices to which the stack packages in accordance with the embodiments are applied, and the memory controller 820 may control the memory 810 to read stored data or store data, in response to a read/write request from a host 830.

While various embodiments have been described above, it will be understood to those skilled in the art that the embodiments described are by way of example only. Accordingly, the stack package and the method for manufacturing the same described herein should not be limited based on the described embodiments.

1. A stack package comprising:
a substrate;
a first semiconductor chip mounted over the substrate;
a support member disposed over the substrate and the first semiconductor chip, and spaced apart from the substrate and the first semiconductor chip;
a plurality of second semiconductor chips stacked over the support member; and
a molding part filling a space between the substrate and the support member and between the first semiconductor chip and the support member, and enclosing the first semiconductor chip, the support member and the second semiconductor chips,
wherein the molding part comprises a first portion which filling a space between the substrate and the support member and between the first semiconductor chip and the support member, and the second portion which is the molding part without the first portion, and
wherein the first portion and the second portion are configured integrally,
wherein the support member is supported by only the molding part without other structure.

2. The stack package according to claim 1, wherein the support member is formed to extend across the substrate in one direction.

3. The stack package according to claim 1, wherein the support member comprises a core substrate or a metal alloy plate.

4. The stack package according to claim 3, wherein the core substrate comprises a glass fiber substrate which is impregnated with resin and the metal alloy plate comprises an alloy plate which contains at least one of FeC and MnCr.

5. (canceled)

6. The stack package according to claim 1, further comprising:
an adhesive member attaching the support member and a lowermost second semiconductor chip.

7. The stack package according to claim 6, wherein the adhesive member is interposed between a bottom surface of the lowermost second semiconductor chip and a top surface of the support member.

8. The stack package according to claim 6, wherein the support member has a mesh shape having a plurality of openings in which the adhesive member is accommodated.

9. The stack package according to claim 8, wherein the adhesive member comprises:
first portions interposed between the bottom surface of the lowermost second semiconductor chip and the top surface of the support member; and
second portions accommodated in the openings.

10. The stack package according to claim 8, wherein the adhesive member is formed to be entirely accommodated in the openings.

11. The stack package according to claim 10, wherein a top surface of the adhesive member is substantially flush with the top surface of the support member, and the top surface of the support member and the bottom surface of the lowermost second semiconductor chip directly contact each other.

12. The stack package according to claim 8, wherein the adhesive member comprises:
first portions interposed between the top surface of the support member and the bottom surface of the lowermost second semiconductor chip;
second portions accommodated in the openings; and
third portions disposed under a bottom surface of the support member.

13. A method for manufacturing a stack package, comprising:
mounting first semiconductor chips over a plurality of unit substrates, respectively, which are formed over a strip substrate;
disposing dams over the strip substrate;
disposing support members over the dams such that the support members are separated from the strip substrate and the first semiconductor chips and extend across the unit substrates; and
stacking a plurality of second semiconductor chips over the support members over the unit substrates.

14. The method according to claim 13, wherein the dams are disposed over both ends of the strip substrate facing away from each other in the one direction.

15. The method according to claim 13, wherein the dams are disposed over both ends of the strip substrate which face away from each other in the one direction and at one or more positions between both the ends of the strip substrate.

16. The method according to claim 13, wherein each of the dams is formed by a plurality of structures arranged in the direction substantially perpendicular to the lengthwise direction of the support members.

17. The method according to claim 13, wherein the dams are formed by a solder resist film or dummy chips.

18. The method according to claim 13, wherein, before the stacking of the second semiconductor chips, the method further comprises:
forming adhesive members under bottom surfaces of the second semiconductor chips,
wherein the stacking of the second semiconductor chips is performed in such a manner that lowermost second semiconductor chips and the support members are attached and the second semiconductor chips are attached, by the medium of the adhesive members.

19. The method according to claim 18, wherein the support members have a mesh shape including a plurality of openings, and the attaching of the lowermost second semiconductor chips is performed in such a manner that portions of the adhesive members formed under bottom surfaces of the lowermost second semiconductor chips are accommodated in the openings.

20. The method according to claim 18, wherein the support members have a mesh shape which includes a plurality of openings, and the attaching of the lowermost second semiconductor chips is performed in such a manner that the adhesive members formed under bottom surfaces of the lowermost second semiconductor chips are entirely accommodated in the openings.
